(19) United States
(12) Patent Application Publication
(10) Pub. No.: US 2005/0121172 A1
(43) Pub. Date: Jun. 9, 2005

(54) Composite heatsink for cooling of heat-generating element

(75) Inventor: Edward Lopatinsky, San Diego, CA (US)

Correspondence Address: ROTYS Inc., 5450 Complex st. # 307, San Diego, CA, 92123, US

(73) Assignee: ROTYS Inc.

(21) Appl. No.: 11/000,625

(22) Filed: Dec. 1, 2004

Related U.S. Application Data
(60) Provisional application No. 60/526,917, filed on Dec. 3, 2003.

(51) Int. Cl. H05K 7/20

(52) U.S. Cl. 165/80.3

(57) ABSTRACT

A composite heatsink for cooling of heat-generating element comprises upper and lower components. The upper component comprises a cover plate and a first set of heat-exchanging means thermally connected with one side of the cover plate. The lower component comprises a base and a second set of heat-exchanging means thermally connected with one side of the base while the other side of the base thermally connected with the heat-generating element. The first set of heat-exchanging means located in alternate order in respect to the second set of heat-exchanging means and thermally connected with the base from a side opposite to the heat-generating element, thus forming a plurality of heat exchange channels. The upper and lower components could be made using the extrusion, forging or die casting technologies. The first and second sets of heat-exchanging means could be made like parallel fins with the same equal spacing located perpendicularly to the cover plate and the base, correspondingly.

### CROSS REFERENCE TO RELATED APPLICATIONS

The present application claims the benefit of priority of U.S. Provisional Patent Application No. 60/526,917, filed Dec. 3, 2003 for Edward Lopatinsky the entire content of which is incorporated herein by reference.

### FIELD OF THE INVENTION

The present invention relates generally to heat-exchanging equipments, and more particularly, to the heatsinks with heat-exchanging means made as fins and/or pins. The present invention is particularly, but not exclusively, useful for cooling systems for regulating the temperature of electronic components.

### BACKGROUND OF THE INVENTION

There are known many types of heatsinks have been known in prior arts. One type of them is the heatsinks comprising a base and heat-exchanging means made as fins and/or pins-fins structures. The most of such heatsinks made as a whole. For example, U.S. Pat. No. 6,667,884 “Heat Dissipating Assembly” comprises the heatsink made as a whole of fins and a base. The base providing thermal contact with the surface of a heat-generating element. These heatsinks are made by using the following types of manufacturing like extrusion, forging or die casting technologies. These types of technologies are the most productive and comparatively least expensive methods.

But, according to these technologies there are some limitations in respect to the distance between fins. The last circumstance becomes critical for further sufficient increasing of heat exchange surface and therefore increasing thermal efficiency of known heatsinks.

Such types of heatsinks with assisted blowers are often used to remove heat from the heat-generating elements like electronic devices. Cooling is important because if left unchecked, heat can cause electronic devices to malfunction during use or lead to premature device failure. As improvements in processor speed occur, the amount of heat generated by the faster processors also increases. The trend toward smaller electronic devices demanding smaller coolers and having larger, faster processors renders the traditional heat removal cooling systems less effective or inadequate. The heatsink of said systems also should be small. According to the modern requirements the heatsinks should have higher heat exchange efficiency at relative small volume.

As well known, the heat exchange efficiency is proportional to the heat exchange surface at all other equal conditions. Therefore, one of the most effective ways for the significant increasing of heat exchange surface of the heatsinks is the increasing of the number of fins by decreasing the fins spacing. These could be realized by the separate manufacturing of fins and base with the following assembling in one for example, by soldering or using the folded fins technology.

For example, U.S. Pat. No. 6,698,500 “Heat Sink with Fins” and No. 6,742,581 “Heat Sink and Fin Module” comprise a group of heat dissipating fins and a base plate. The fins are inserted into grooves formed in the base. Such technology allows decreasing the distance between fins and, consequently, increasing the heat exchange surface at the same volume of the heatsink.

But, such junction of the fins with the base leads to arising additional thermal resistance between the base and the fins and, therefore, to some decreasing of heat exchange efficiency of the heatsink. And more, such known heatsink design requires more expensive technologies.

It would be desirable to provide more thermal efficient design of a heatsink for cooling of heat-generating element with a relative simple and inexpensive fabrication of it. A proposed heatsink would overcome these problems associated with the contradiction between the tendency of further enhancement of the cooling efficiency by decreasing of the distance between the fins and excluding arising additional thermal resistance.

### SUMMARY OF THE INVENTION

According to the present invention the general idea is to increase the heat-exchanging surface at the same volume of the heatsink due to the smaller spacing between heat-exchanging means without arising additional thermal resistance.

In order to achieve these objectives, a composite heatsink for cooling of heat-generating element comprises upper and lower components. The upper component comprises a cover plate and a first set of heat-exchanging means thermally connected with one side of the cover plate. The lower component comprises a base and a second set of heat-exchanging means thermally connected with one side of the base while the other side of the base thermally connected with the heat-generating element. The first set of heat-exchanging means located in alternate order in respect to the second set of heat-exchanging means and thermally connected with the base from a side opposite to the heat-generating element, thus forming a plurality of heat exchange channels.

According to the preferred embodiment each of the upper and lower components is made as a whole of high heat conductive material. The upper and lower components could be made using the extrusion, forging or die casting technologies. The first and second sets of heat-exchanging means could be made like parallel fins with the same equal spacing located perpendicularly to the cover plate and the base, correspondingly. According to another variant of the heat-exchanging means manufacturing the first and second sets of heat-exchanging means could be made like pins-fins structures with the same equal spacing located perpendicularly to the base and the cover plate, correspondingly.

For more even temperature distribution the second set of heat-exchanging means could be thermally connected with the cover plate. The cover plate in this case will serve as a heat spreader.

The thermal connection between the first set of heat-exchanging means and the base could be made by soldering. According to the preferred embodiment there is a set of grooves to increase the contact surface between the first set of the parallel fins and the base. These grooves made on the base from the side opposite to the heat-generating element and located between the parallel fins of the second set of heat-exchanging means and spaced apart from each other by the same equal spacing. The grooves have a width and a depth equal to at least the thickness of the parallel fins, thus the grooves are matched with tips of the parallel fins of the first set of heat-exchanging means. In this case the thermal resistance between the base and the first set of the parallel fins will be negligible.

The foregoing and other objectives, features and advantages of the invention will be more readily understood upon consideration of the following detailed description of the invention, taken in conjunction with the accompanying drawings.

### BRIEF DESCRIPTION OF THE DRAWINGS

FIG. 1 is a top perspective view showing the composite heatsink for cooling of heat-generating element.

FIG. 2 is a front view showing the composite heatsink for cooling of heat-generating element.

FIG. 2A is an enlarged A view from FIG. 2.

FIG. 3 is a top perspective view showing the upper component.

FIG. 4 is a top perspective view showing the lower component.

### DETAILED DESCRIPTION OF PREFERRED EMBODIMENTS

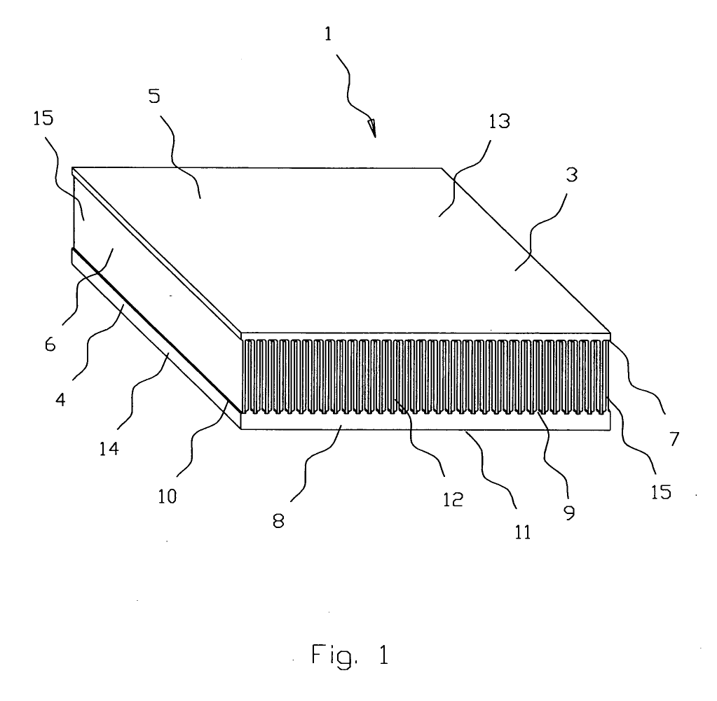

Preferred embodiment of the present invention will be described in detail below with reference to the accompanying drawings. FIGS. 1-4 show embodiment of the present invention.

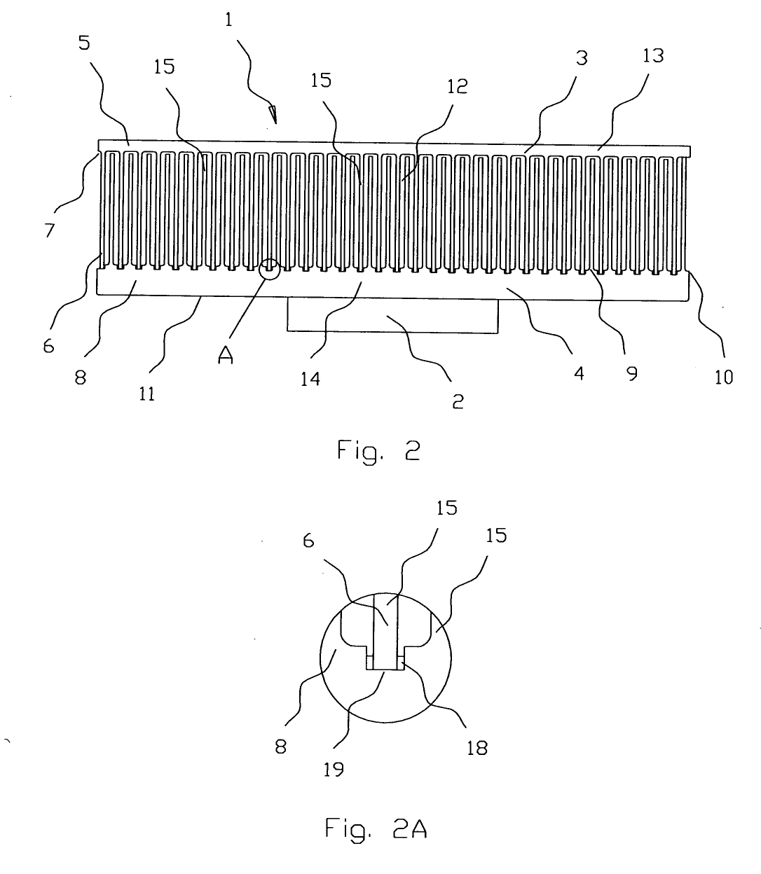

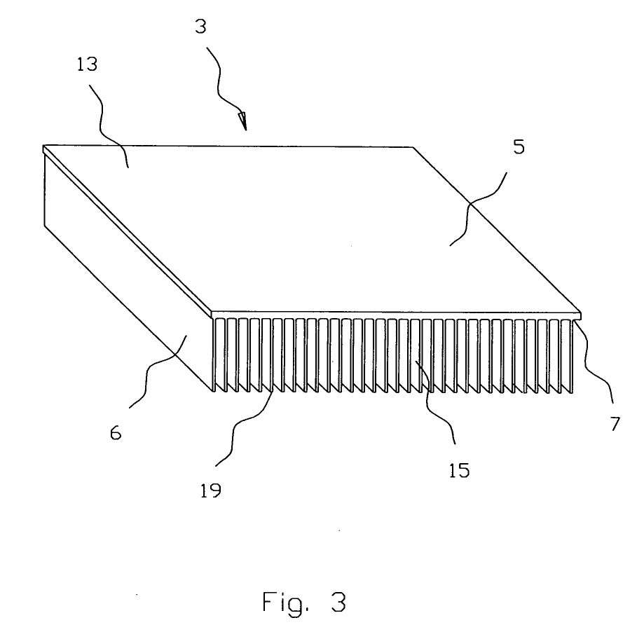

A composite heatsink 1 (FIG. 1-2) for cooling of heat-generating element 2 comprises upper 3 and lower 4 components. The upper component 3 (FIG. 3) comprises a cover plate 5 and a first set 6 of heat-exchanging means thermally connected with one side 7 of the cover plate 5.

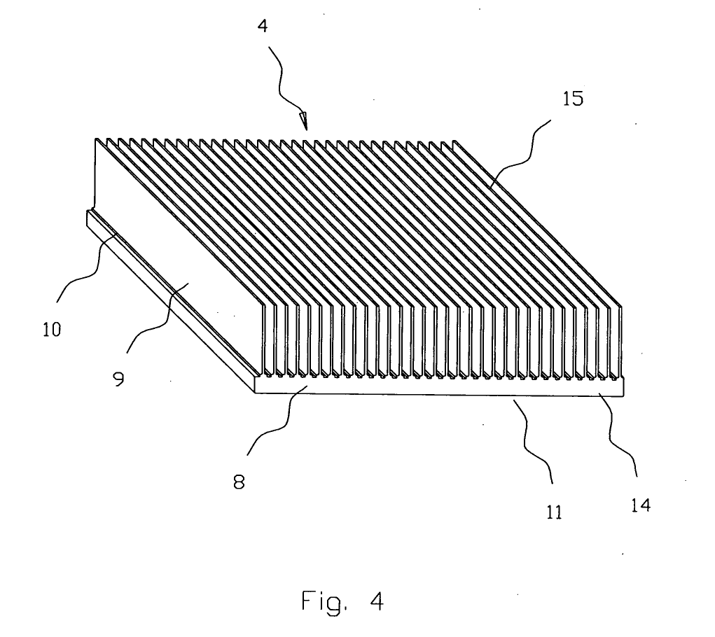

The lower component 4 (FIG. 4) comprises a base 8 and a second set 9 of heat-exchanging means thermally connected with one side 10 of the base 8 while the other side 11 of the base 8 thermally connected with the heat-generating element 2. The first set 6 of heat-exchanging means located in alternate order in respect to the second set 9 of heat-exchanging means and thermally connected with the base 8 from a side 10 opposite to the heat-generating element 2, thus forming a plurality of heat exchange channels 12.

According to the preferred embodiment each of the upper 3 and lower 4 components is made of high heat conductive material as upper 13 and lower 14 wholes. These upper 13 and lower 14 wholes could be made using the extrusion, forging or die casting technologies. The first 6 and second 9 sets of heat-exchanging means could be made like parallel fins 15 with the same equal spacing located perpendicularly to the cover plate 5 and the base 8, correspondingly. According to another variant of the heat-exchanging means manufacturing the first 6 and second 9 sets of heat-exchanging means could be made like pins-fins structures (not shown on Figs.) with the same equal spacing located perpendicularly to the base 8 and the cover plate 5, correspondingly.

For more even temperature distribution the second set 9 of heat-exchanging means could be thermally connected with the cover plate 5 for example by soldering. The cover plate 5 in this case will be serves like a heat spreader.

The thermal connection between the first set 6 of heat-exchanging means and the base 8 could be made by soldering. According to the preferred embodiment for increasing of the contact surface between the parallel fins 15 and the base 8, the base 8 from the side 10 opposite to the heat-generating element 2 further comprising grooves 18. The grooves 18 are located between the parallel fins 15 of the second set 9 of heat-exchanging means and spaced apart from each other by the equal spacing. The grooves 18 have a width and a depth equal to at least the thickness of the parallel fins 15, thus the grooves 18 are matched with tips 19 of the parallel fins 15 of the first set 6 of heat-exchanging means. In this case the thermal resistance between the base 8 and the first set 6 of the parallel fins 15 will be negligible.

The composite heatsink 1 according to the preferred embodiment of the present invention could be manufacturing by the following way. At the first step the upper 13 and lower 14 wholes being made separately by extrusion of high heat conductive material, for example from copper. For both wholes 13 and 14 the heat-exchanging means being made like the parallel fins 15 with the same equal spacing located perpendicularly to the cover plate 5 and the base 8, correspondingly. During the same extrusion process for the lower wholes 14 the grooves 18 being formed at the base 8 from the side 10 and located between the parallel fins 15 of the second set 9 of heat-exchanging means and spaced apart from each other by the same equal spacing.

At the second step a solder material being placed along the surfaces of the grooves 18 and both upper 13 and lower 14 wholes being disposed one to respect another, thus the tips 19 of the parallel fins 15 of the first set 6 matched with the grooves 18.

And, at the last step, the assembly loaded by weight from the upper side of the upper wholes 13 and being placed inside the heat chamber at the temperature above the melting temperature of the corresponding solder material.

The composite heatsink 1 according to the present invention allows to forms relative narrow heat exchange channels while the components 3 and 4 made as wholes. Therefore, such design provides the larger heat exchange surface at the same volume in comparison with known heatsinks without arising additional thermal resistance. Therefore, the composite heatsink 1 has increased heat exchange efficiency and could be manufacturing by using the inexpensive well-known technology.

1. A composite heatsink for cooling of heat-generating element comprising an upper and a lower components, wherein:
(i) said upper component comprising a cover plate and a first set of heat-exchanging means thermally connected with one side of said cover plate;
(ii) said lower component comprising a base and a second set of heat-exchanging means thermally connected with one side of said base while the other side of said base thermally connected with said heat-generating element;
(iii) said first set of heat-exchanging means being located in alternate order in respect to said second set of heat-exchanging means and being thermally connected with said base from a side opposite to said heat-generating element, thus forming a plurality of heat exchange channels.

2. The composite heatsink as claimed in claim 1, wherein said first and second sets of heat-exchanging means being thermally connected with said cover plate and said base, correspondingly, by soldering.

3. The composite heatsink as claimed in claim 1, wherein each of said upper and lower components being made as a whole of high heat conductive material.

4. The composite heatsink as claimed in claim 3, wherein said upper and lower components being made by extrusion.

5. The composite heatsink as claimed in claim 3, wherein said upper and lower components being made by forging.

6. The composite heatsink as claimed in claim 3, wherein said upper and lower components being made by die casting.

7. The composite heatsink as claimed in claim 1, wherein said first and second sets of heat-exchanging means being made like parallel fins with the same equal spacing located perpendicularly to said cover plate and said base, correspondingly.

8. The composite heatsink as claimed in claim 1, wherein said first and second sets of heat-exchanging means being made like pins-fins structures with the same equal spacing located perpendicularly to said base and said cover plate, correspondingly.

9. The composite heatsink as claimed in claim 1, wherein said second set of heat-exchanging means being thermally connected with said cover plate.

10. The composite heatsink as claimed in claim 1, wherein said first set of heat-exchanging means being thermally connected with said base by soldering.

11. The composite heatsink as claimed in claim 7, wherein said base from said side opposite to said heat-generating element further comprising grooves, wherein:
(i) said grooves being located between said parallel fins of said second set of heat-exchanging means and spaced apart from each other by said equal spacing;
(ii) said grooves having a width and a depth equal to at least the thickness of said parallel fins, thus said grooves being matched with tips of said parallel fins of said first set of heat-exchanging means.
